(19) United States
(12) Patent Application Publication
(10) Pub. No.: US 2009/0072373 A1
(43) Pub. Date: Mar. 19, 2009

(54) PACKAGED INTEGRATED CIRCUITS AND METHODS TO FORM A STACKED INTEGRATED CIRCUIT PACKAGE

(76) Inventors: Reynaldo Corpuz Javier, Plano, TX (US); Jayprakash V. Chipalkatti, Dallas, TX (US); Alok K. Lohia, Dallas, TX (US)

Correspondence Address: TEXAS INSTRUMENTS INCORPORATED, P O BOX 655474, M/S 3999, DALLAS, TX, 75265, US

(21) Appl. No.: 11/855,784

(22) Filed: Sep. 14, 2007

(51) Int. Cl. H01L 23/02; H01L 21/00

(52) U.S. Cl. 257/686; 438/109; 257/E23.18

(57) ABSTRACT

Packaged integrated circuits and methods to form a thermal stacked integrated circuit package are disclosed. A disclosed method comprises attaching a first integrated circuit to at least one of a plurality of pads of a substrate, mounting a second integrated circuit above the first integrated circuit, placing a heat conductor in thermal contact with a top surface of the second integrated circuit, and encapsulating the first and second integrated circuits while leaving a surface of the heat conductor exposed to dissipate heat.

### TECHNICAL FIELD

The present disclosure pertains to semiconductor packaging and, more particularly, to packaged integrated circuits and methods to form a stacked integrated circuit package.

### BACKGROUND

Consumer electronic devices in recent years have become more powerful and smaller at the same time. To make consumer electronic devices more powerful without requiring more space, integrated circuits associated with electronic devices have integrated more functions and more controls. The desire of consumers for more processing power has not abated, but instead, continues to grow. At the same time, consumers want electronic devices to be small and quiet.

Increased processing power requires additional circuitry, which further requires additional space on the printed circuit board of an electronics device. One method to reduce the space that integrated circuits consume on the printed circuit board is to stack integrated circuits on top of each other. By stacking integrated circuits, multiple integrated circuits can be incorporated without requiring more space.

### BRIEF DESCRIPTION OF THE DRAWINGS

FIG. 1 is an illustration of an example packaged integrated circuit.

FIG. 2 is a flowchart representative of an example process to create the example packaged integrated circuit of FIG. 1.

FIGS. 3A-3G are illustrations of an example semiconductor device at different stages of the example process of FIG. 2.

FIG. 4 is an illustration of another example packaged integrated circuit with an example heat sink attached.

FIG. 5 is a flowchart representative of another example process to create another example packaged integrated circuit.

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### SUMMARY

Packaged integrated circuits and methods to form a thermal stacked integrated circuit package are described. In some examples, a packaged integrated circuit comprises a first integrated circuit, a second integrated circuit above the first integrated circuit, and a heat conductor placed on the second integrated circuit. A mold encapsulates the first and second integrated circuits and a portion of the heat conductor. However, the mold exposes a surface of the heat conductor on at least one surface of the packaged integrated circuit and the exposed portion of the heat conductor is positioned on a surface that does not include a contact to the first integrated circuit.

### DETAILED DESCRIPTION

Packaged integrated circuits and methods to form a thermal stacked packaged integrated circuit will now be disclosed. As described herein, an integrated circuit is a die or a chip containing at least one active semiconductor device (e.g., an NPN transistor, etc.). Thus, for example, an integrated circuit may contain a single active device (e.g., a transistor) or the integrated circuit may contain multiple active devices (e.g., a processor having millions of transistors).

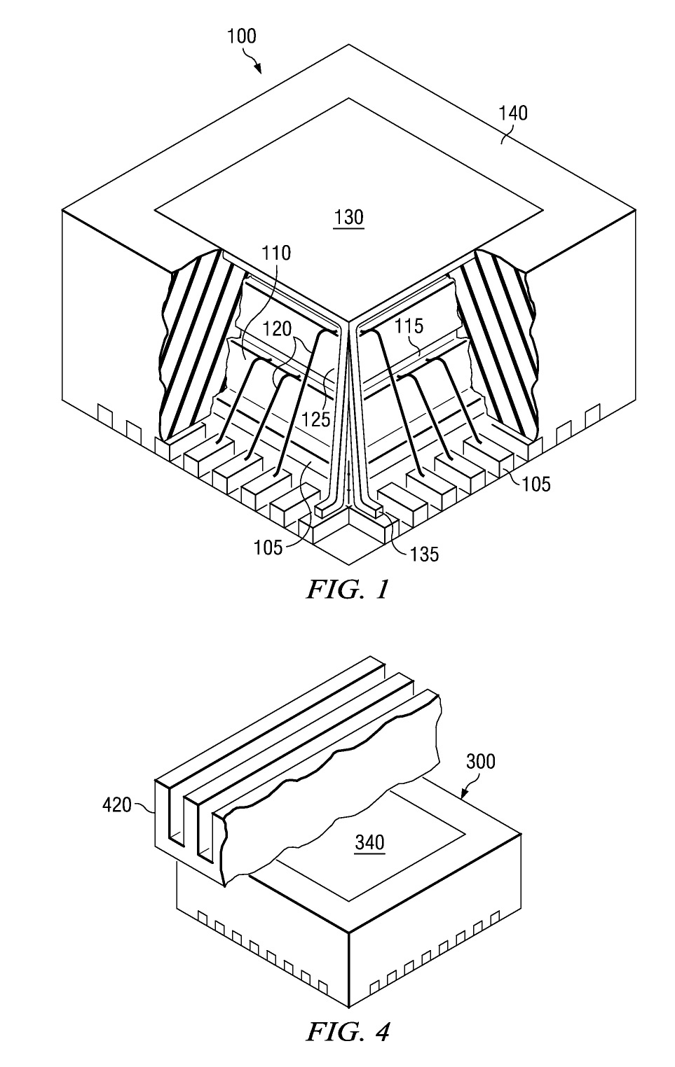

FIG. 1 illustrates an example high thermal performance stacked packaged integrated circuit 100. In the example of FIG. 1, the packaged integrated circuit 100 is integrated into a quad flat no-lead (QFN) package. However, the packaged integrated circuit 100 may be integrated into any type of package (e.g., a leadframe land grid array, etc.). Generally, an integrated circuit packaged in a QFN package has a plurality of pads 105 that are exposed on at least one surface of the packaged integrated circuit 100. A first integrated circuit 110 is directly attached to a first pad 105 using any technique (e.g., epoxy, eutectic, solder, etc.). A spacer layer 115 is then attached to the top surface of the first integrated circuit 110. Generally, heat that the first integrated circuit 110 generates is dissipated via the first pad 105. To facilitate head dissipation, in the example of FIG. 1, the first pad 105 is exposed at the bottom of the packaged integrated circuit 100. The first integrated circuit 110 may also be attached to other bond pads, either directly or via bond wires. In the example of FIG. 1, a bond wire 120 couples the first integrated circuit 110 to a second pad 105 of the packaged integrated circuit 100.

In the example of FIG. 1, a second integrated circuit 125 is attached to the spacer layer 115 using any technique. At least one bond wire 120 couples the second integrated circuit 125 to a pad 105 (e.g., the first pad, the second pad, or on the third pad). To remove heat via a different surface of the packaged integrated circuit 100, a heat conductor 130 is included. The heat conductor 130 of the illustrated example includes at least one support member 135. The heat conductor 130 contacts a portion of a top surface of the second integrated circuit 125. Additionally, the support member 135 contacts at least one pad 105 for support (e.g., placement, etc.) and to provide a heat dissipation channel. A mold 140 substantially encapsulates the packaged integrated circuit 100 to protect the integrated circuits 110, 125 and bond wires 120 from the environment. However, the pads 105 are generally exposed on at least one surface of the packaged integrated circuit 100 to facilitate electrical connection with a printed circuit board of an electronics device.

In addition, the heat conductor 130 of the illustrated example is exposed on at least one surface of the packaged integrated circuit 100 to dissipate heat from the integrated circuits 110, 125 of the packaged integrated circuit 100. Generally, the heat conductor 130 is configured to remove heat from the second die 125, but, in some examples, the heat conductor 130 may also remove heat from the first integrated circuit 110. For example, if the first integrated circuit 110 generates more heat than the second integrated circuit 125, heat from the first integrated circuit may flow into the second integrated circuit and out of the packaged integrated circuit 100 via the heat conductor 130.

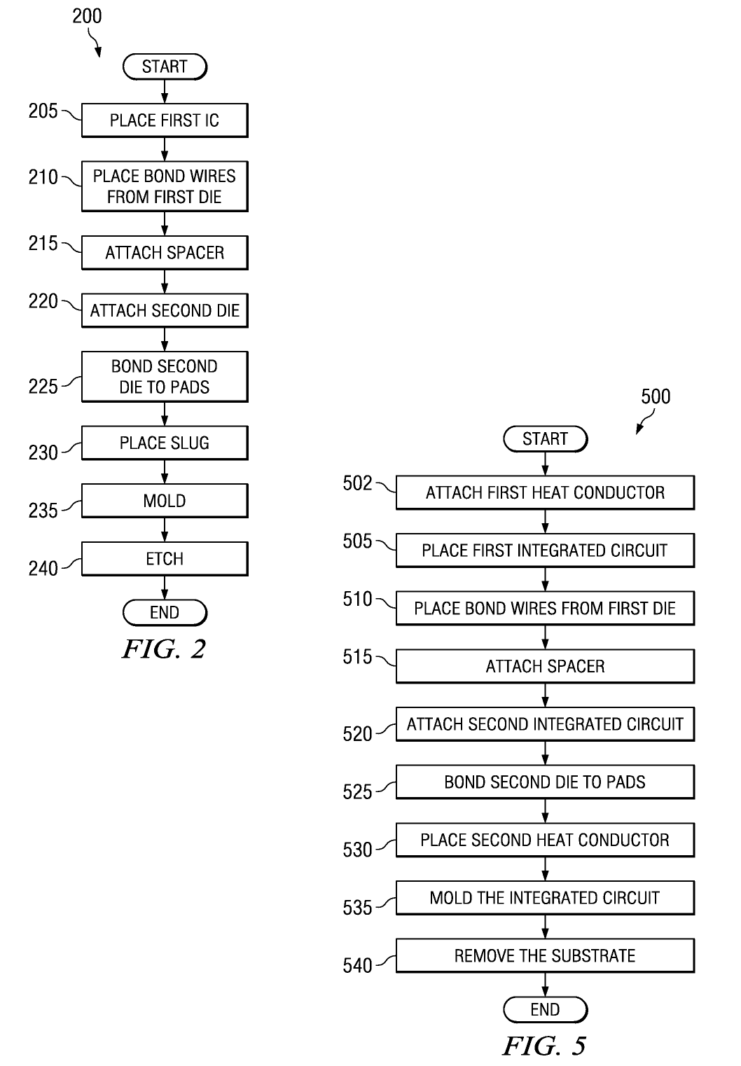

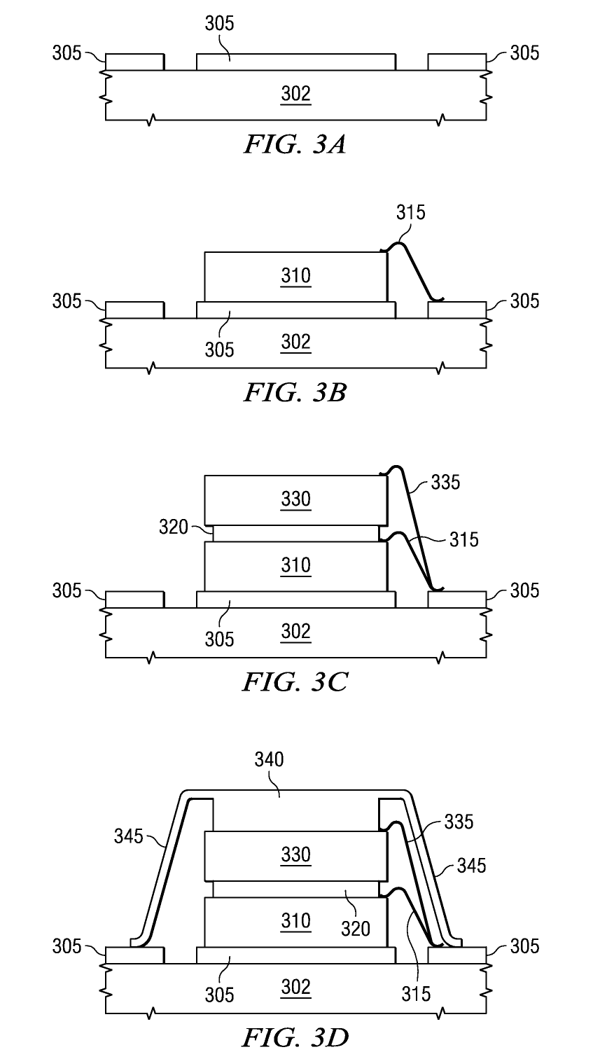

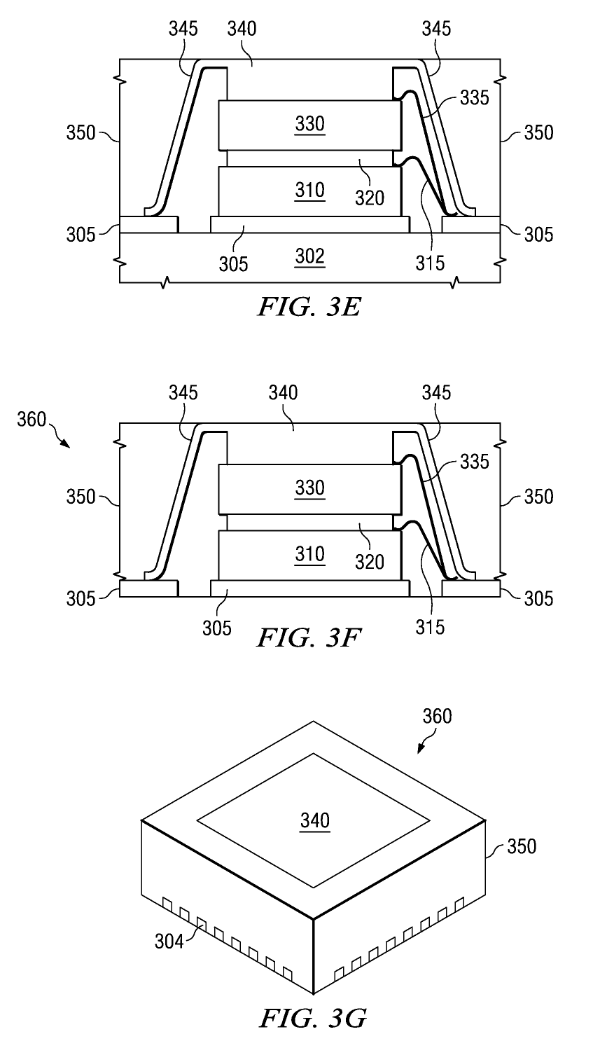

FIG. 2 illustrates an example process 200 to manufacture the packaged integrated circuit of FIG. 1, which will be discussed in conjunction with the examples of FIGS. 3A-3G. FIGS. 3A-3G illustrate an example packaged circuit at different stages of the example process 200. Initially, the example process 200 begins with a blank leadframe or a blank package (e.g., a QFN package, etc.). In the example of FIG. 3A, the blank package includes a substrate 302 having a plurality of pads 305. The pads 305 are made of any electrically conductive material and are adapted to receive devices and components associated with the example circuit (e.g., bond wires, integrated circuits, etc.).

In the example of FIG. 3B, a first integrated circuit 310 is attached to a pad 305 of the substrate 302 using any technique (e.g., solder, epoxy, eutectic, etc.) (block 205). After the first integrated circuit 310 is attached, bond wires 315 are placed between the pads 305 and respective contacts of the integrated circuit 310 (block 210). The bond wires 315 may be placed by using any technique (e.g., bell bond, stand-off-stitch bond, wedge bond, etc.) and may be made of any material (e.g., copper, gold, aluminum, etc.). After placing the bond wires 315, as illustrated in the example of FIG. 3C, a spacer layer 320 is attached to the first integrated circuit 310 to protect the bond wires 315 (block 215). The spacer layer 320 is generally made of a non-conductive material (e.g., silicon) and creates an offset space so that another integrated circuit can be attached above the first integrated circuit 310.

The second integrated circuit 330 is attached to the spacer layer 320 using any technique (e.g., eutectic, epoxy, solder, etc.) (block 220). Bond wires 335 are then placed between contacts of the second integrated circuit 330 and respective one(s) of the pads 305 (block 225). In the example of FIG. 3C, the bond wires are illustrated on one side of the integrated circuits for clarity. However, bond wires may be placed on any side of the integrated circuits 310 and 330.

After bonding the second integrated circuit 330 to the pads 305, as illustrated in the example of FIG. 3D, a heat conductor 340 having a body 342 is placed above and in contact with the second integrated circuit 330 (block 230). The heat conductor 340 is made of any suitable material (e.g., metals, carbon graphite, etc.) to dissipate heat from the integrated circuits 310, 330 to a cooler surface, thereby reducing the temperature of the integrated circuits 310, 330. To support the heat conductor 340, the heat conductor 340 is provided with at least one support member 345. The support member(s) extend from the body and are supported on at least one pad 305. In the example of FIG. 3D, neither the body of the heat conductor 340 nor the support members 345 contact the bond wires 315 and 345. In addition, the heat conductor 340 and the support members do not encapsulate the integrated circuits 310, 330 and the bond wires 315, 335. However, in some examples, the heat conductor 340 may encapsulate the integrated circuits 310, 325 and the bond wires 315, 335 to allow heat to conduct via a plurality of surfaces.

After placing the heat conductor 340, a molding process is applied to form a mold 350 over the integrated circuits 310 and 330, the bond wires 315 and 335, and a portion of the heat conductor 340 (block 235). In the illustrated example, a mold 350 is a material that encapsulates and seals the integrated circuits 310, 330. Generally, the mold 350 may be implemented by any suitable material (e.g., an epoxy, a ceramic, a plastic material, etc.) to protect the integrated circuits 310 and 330, the bond wires 315 and 335, and the encapsulated portion of the heat conductor 340 from the environment. In the example of FIG. 3E, after the mold 350 is formed, the integrated circuits 310 and 330 and the bond wires 315 and 335, are completely encapsulated inside of the mold 350 and cannot move. Thus, the molding process seals and protects both the bond wires 315, 335 and the integrated circuits 310, 330 from the environment. For example, prior to the molding process, the bond wires 315, 330 could be adjusted by contacting a bond wire. After the molding process (block 208), the bond wires 315, 330 are encapsulated and shielded from movement by the mold 350. However, the mold 350 exposes at least one surface of the heat conductor 340 to the environment to conduct heat from the integrated circuits 310, 330.

After creating the mold 350 (block 235), some or all of the substrate 302 is removed to form a packaged integrated circuit 360 (block 240). In the example of FIG. 3E, the substrate 302 is removed via any suitable process. This process is selected based on the material of the substrate. For example, an etch process may be implemented to remove the substrate without damaging the packaged integrated circuit 360. After removing the substrate 302, the pads 305 remain attached to the packaged integrated circuit 360, thereby forming the electrical contacts of the packaged integrated circuit 360. FIG. 3G illustrates a three-dimensional view of the packaged integrated circuit 360. In FIG. 3G, the pads 305 and at least a portion of the heat conductor 340 are exposed to the environment. In the example of FIG. 3G, the packaged integrated circuit forms a quad flat no-lead (QFN) package.

The example process 200 of FIG. 2 ends after the substrate 302 is removed. Although the foregoing describes a particular sequence of operations, the sequence of operations of the example process 200 may vary. For example, the stages of the process may be rearranged, combined, or divided. Alternatively or additionally, additional stages, processes or operations may be added. For example, a plating process may be implemented to form a standoff (e.g., a plate) above the contacts of the packaged integrated circuit to form a larger contact for the example packaged integrated circuit. In some examples, the plating process may create a stand-off so that the packaged integrated circuit rests above the surface (e.g., a printed circuit board, etc.). The plating process may be implemented by any technique (e.g., solder wave, screen print, etc.). For example, a bumping process may form interconnect elements (e.g., solder balls) that may be used to attach the packaged integrated circuit to a surface (e.g., a printed circuit board, etc.).

In some examples, a second heat sink may be attached to the packaged integrated circuit having an exposed heat conductor. FIG. 4 illustrates the example packaged integrated circuit 300 with a heat sink 420 attached thereto. In the example of FIG. 4, a thermal interface (not shown) such as a thermal heat sink compound may also be applied to the exposed heat conductor 340 of the packaged integrated circuit 300. The thermal interface fills in small, microscopic gaps between the heat sink 420 and the heat conductor 340, thereby eliminating air gaps and improving improve thermal performance. The heat sink 420 of the illustrated receives the heat from the packaged integrated circuit 300 by maintaining a cooler quiescent temperature (e.g., by convection due to a lower environmental temperature). As a result of the removal of heat from the packaged integrated circuit 300, the temperature of the packaged integrated circuit 400 decreases, thereby decreasing the temperature of the integrated circuits contained therein.

In some examples, a pad 305 may not receive the first integrated circuit on the substrate. To remove heat from such a packaged integrated circuit, a second heat conductor may be included to conduct heat to the bottom surface of the packaged integrated circuit. FIG. 5 illustrates an example process 500 to form a packaged integrated circuit with such a second heat conductor.

The example process 500 begins with a blank leadframe or a substrate. In the example of FIG. 5, the leadframe may be any suitable material (i.e., a leadframe with metal plating, a copper alloy substrate, etc.), which may include a plurality of pads 305. The pads are made of any electrically conductive material (e.g., copper, gold, aluminum, metal alloys, etc.) and are adapted to receive devices and components associated with the example circuit (e.g., bond wires, integrated circuits, etc.).

In the example of FIG. 5, the example process 500 begins by attaching a first heat conductor to a substrate using any technique (block 502). After attaching the first heat conductor, a first integrated circuit is attached to the first heat conductor using any technique (block 505). Bond wires are placed between the pads and a plurality of contacts of the integrated circuit (block 510). After placing the bond wires, a spacer layer is placed on the first integrated circuit to protect the bond wires (block 515).

The second integrated circuit is then attached to the spacer layer using any technique (block 520). Bond wires are then placed between contacts of the second integrated circuit and the pads (block 525). After wire bonding the second integrated circuit to the pads, a second heat conductor is placed above the second integrated circuit (block 530). The second heat conductor contacts a portion of the second integrated circuit and is, thus, positioned to remove heat from the second integrated circuit. After placing the second heat conductor, a molding process forms a mold over the integrated circuits, bond wires, and portion(s) of the heat conductors (block 535). However, as described above, a portion of the second heat conductor is exposed. After creating the mold (block 535), the substrate is removed to expose the first heat conductor and the pads on the bottom side of the packaged integrated circuit (block 540). In the example of FIG. 5, the substrate is removed via any suitable process (selected based on the material of the substrate). For example, an etch process may be implemented to remove the substrate without damaging or removing the pads of the packaged integrated circuit. After removing the portion of the substrate, the pads remain attached to the packaged integrated circuit, thereby forming the electrical contacts of the packaged integrated circuit.

In view of the foregoing, improved packaged integrated circuits methods to manufacture a high thermal performance packaged integrated circuit are disclosed. In the illustrated examples, at least a portion of a heat conductor is exposed on at least one surface of the packaged integrated circuit. As a result, two high power integrated circuits can be stacked on top of each other and sufficiently cooled through the heat conductor by a second heat sink or by convection. The bottom-most integrated circuit may conduct heat via a pad exposed at the bottom surface of the packaged integrated circuit (i.e, the surface of a packaged integrated circuit attached to a printed circuit board) and the top-most integrated circuit may conduct heat via the portion of the heat conductor exposed on the top surface of the packaged integrated circuit. In the described examples, to implement a heat conductor exposed on the top surface, the heat conductor is added to the structure before molding, thereby requiring minimal process changes.

Although certain methods, apparatus, and articles of manufacture have been described herein, the scope of coverage of this patent is not limited thereto. On the contrary, this patent covers all apparatuses, methods and articles of manufacture fairly falling within the scope of the appended claims either literally or under the doctrine of equivalents.

What is claimed is:

1. A packaged integrated circuit, comprising:
a first integrated circuit;
a second integrated circuit above the first integrated circuit;
a heat conductor placed on the second integrated circuit; and
a mold substantially containing the first and second integrated circuits and a portion of the heat conductor, the mold exposing a surface of the heat conductor on at least one surface of the packaged integrated circuit, wherein the exposed portion of the heat conductor is positioned on a surface that does not include a contact to the first integrated circuit.

2. A packaged integrated circuit as defined in claim 1, further comprising a substrate having the contact.

3. A packaged integrated circuit as defined in claim 1, wherein a contact of the first integrated circuit is coupled to a first pad forming the contact of the packaged integrated circuit, and wherein a contact of the second integrated circuit is coupled to a second pad of the packaged integrated circuit.

4. A packaged integrated circuit as defined in claim 1, wherein a support member of the heat conductor contacts at least one pad of the packaged integrated circuit.

5. A packaged integrated circuit as defined in claim 1, wherein the heat conductor is to conduct heat from the second integrated circuit to the surface of the packaged integrated circuit.

6. A packaged integrated circuit as defined in claim 1, further comprising a heat sink in thermal contact with the exposed surface of the heat conductor to conduct heat from the packaged integrated circuit.

7. A packaged integrated circuit as defined in claim 1, wherein the exposed surface of the heat conductor is located on a top surface of the packaged integrated circuit, and a bottom surface of the packaged integrated circuit is exposed and the bottom surface is attached to a printed circuit board.

8. A packaged integrated circuit as defined in claim 1, wherein the packaged integrated circuit is a quad flat no-lead package.

9. A method of forming a packaged integrated circuit, comprising:
attaching a first integrated circuit to at least one of a plurality of pads of a substrate;
mounting a second integrated circuit above the first integrated circuit;
placing a heat conductor in thermal contact with a top surface of the second integrated circuit; and
encapsulating the first and second integrated circuits while leaving a surface of the heat conductor exposed to dissipate heat.

10. A method as defined in claim 9, further comprising removing at least a portion of the substrate to expose the pads.

11. A method as defined in claim 9, further comprising coupling a first end of a first bond wire to a first one of the pads and a second end of the first bond wire to a contact of the first integrated circuit, and coupling a first end of a second bond wire to a second one of the pads and a second end of the second bond wire to a contact of the second integrated circuit.

12. A method as defined in claim 9, wherein at least one support member of the heat conductor contacts at least one of the pads.

13. A method as defined in claim 9, wherein the heat conductor contacts the second integrated circuit to receive heat from at least one of the first integrated circuit or the second integrated circuit.

14. A method as defined in claim 9, wherein the heat conductor comprises a metal slug.

15. An electronic system, comprising:
a circuit board;
a packaged integrated circuit having a first integrated circuit attached to a pad, a second integrated circuit mounted above the first integrated circuit, a heat conductor mounted above the second integrated circuit, and a mold substantially containing the first and second integrated circuit and the heat conductor, the mold exposing a portion of the heat conductor to remove heat from the packaged integrated circuit.

16. An electronic system as defined in claim 16, further comprising a heat sink coupled to the exposed portion of the packaged integrated circuit to receive heat from the packaged integrated circuit.

17. An electronic system as defined in claim 16, wherein the heat conductor is in thermal contact with the second integrated circuit.

18. An electronic system as defined in claim 16, wherein the packaged integrated circuit is a quad flat no-lead package.

19. An electronic system as defined in claim 16, further comprising a second heat conductor in thermal contact with a bottom surface of the first integrated circuit.
